(19) United States
(12) Patent Application Publication
(10) Pub. No.: US 2016/0378887 A1
(43) Pub. Date: Dec. 29, 2016

(54) Augmented Reality for Architectural Interior Placement

(71) Applicant: Juan Elias Maldonado, Brigantine, NJ (US)

(72) Inventor: Juan Elias Maldonado, Brigantine, NJ (US)

(73) Assignee: Juan Elias Maldonado, Brigantine, NJ (US)

(21) Appl. No.: 15/157,503

(22) Filed: May 18, 2016

Related U.S. Application Data
(60) Provisional application No. 62/183,736, filed on Jun. 24, 2015.

(51) Int. Cl. G06F 17/50; G06Q 10/06; G06Q 30/06; G06Q 10/08; G06T 19/00; G06T 17/00

(52) U.S. Cl. CPC G06F 17/5004; G06T 19/006; G06T 17/00; G06Q 30/0635; G06Q 10/087; G06Q 10/067; G06T 2207/30108; G06T 2200/04

(57) ABSTRACT

The invention is a method for utilizing an augmented reality headset with user generated 3D object holograms or third party vendor generated 3D model holograms to be placed or superimposed, upon a real world environment. The purpose is for interior design object placement and planning.

### BACKGROUND

Field of the Invention

The present invention is a method for interior design in which a user utilizing an augmented reality headset can place furniture, electronics, and other objects from either their own personal photo gallery or online third party vendors into their real world environment.

Description of the Related Art

Interior design and interior planning is mainly done through the labor intensive and time consuming process of obtaining measurements of rooms and measurements of objects to be placed in the room. Afterwards, a person inputs the measurements into computer software and renders a mock-up of what the interior place could look like. Unfortunately, the mock-ups are just that, a draft of what something could look like; no real world items are in the rendering and it is not a replacement for real world object placement.

The current way to plan interior decoration or planning is through computer software with generic 3D models on a flat 2D monitor. The software is usually a CAD (Computer Aided Design) program. In recent years, virtual and augmented reality have become the latest technology in visual immersion. The present invention seeks to combine the technology of augmented reality with interior design and planning.

### SUMMARY

The present invention allows for users to use an augmented reality headset where they are able to see their real world environment, yet place 3D models holograms of furniture and other objects both personally owned by the user and accessed from third party vendor sites.

The purpose of the invention is a method to make interior design object placement and planning easier and done in real-time in the real world rather than within some software program on a desktop or laptop computer displayed on a 2D monitor.

### BRIEF DESCRIPTION OF THE DRAWINGS

FIG. 1 describes the flow of the process for interior design through augmented reality.

### REFERENCE NUMERALS IN THE DRAWING

2 Cellphone
4 Camera functionality of cellphone
6 Software to convert photos to a 3D model
8 Cloud storage
10 Augmented reality headset
12 Inventory list within software
14 Augmented reality of a 3D space with holographic 3D objects
16 Shopping cart function within software
18 Checkout function within software

### DETAILED DESCRIPTION

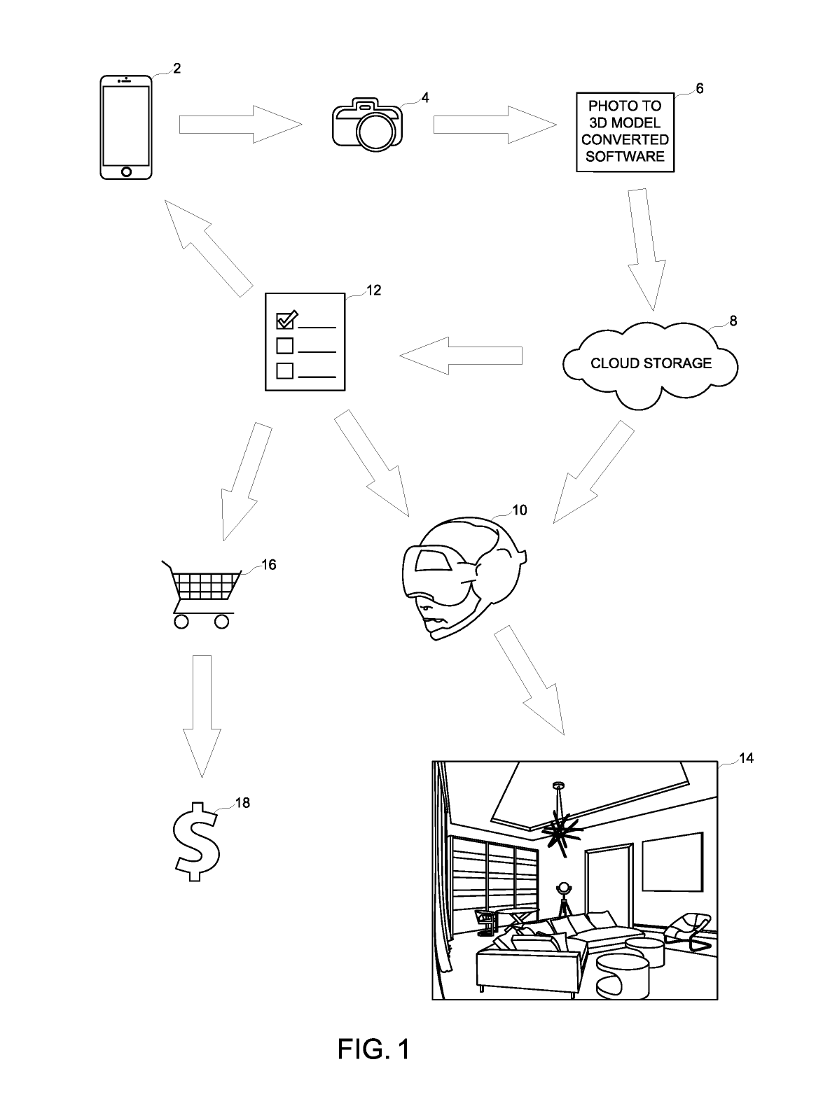

The invention is a method for integrating augmented reality with interior design object placement in the real world using holograms. Using FIG. 1 as a reference point, a user would start with using their personal cellphone, element #2, to take photos, element #4, of their personal furnishing in their current home that they wish to use within the software. Typically, the photos required would be a top, side, front and perspective view of the object. The user would then input the photos into a third party photo to 3D model converter program, element #6, which would create a 3D model of the object photographed. The 3D model would then be uploaded to a cloud storage database, element #8. The software would then create an inventory list of user generated 3D models for the user to access easily later, element #12. From the cloud storage, element #8, the user can download 3D models that were created directly into the onboard memory of the augmented reality device, element #10. From the augmented reality headset, element #10, the user can then begin placing holographic representations of the 3D objects in real world space as indicated by the line drawing in element #14. The user can also access third party vendor websites who sell furniture, appliances, and other objects through the augmented reality headset, element #10, or their cellphone, element #2, and upload the 3D models to cloud storage as well, element #8. The user can also save third party vendor objects into their own inventory list as well, element #12. Afterwards, the user can proceed to select third party vendor items from their inventory list, element #12, and proceed to add them to a virtual shopping cart, element #16, and proceed to a virtual checkout, element #18, for purchase. The method involves streamlining the process of interior design by allowing interior design placement and planning to occur within an augmented reality headset using holograms of real objects in the real world and linking the ability to purchase third party vendor items within the same application. The app would work best with vacant buildings, but could be used with furnished homes with the new furnishings overlaying the real ones.

Also, the user can take photos of their own home furnishing and have them projected onto 3D objects in the new home to see what their own belongings would look like placed in the vacant home.

The user will also be able to output a digital file containing a virtual blueprint of the space containing their holograms utilizing the augmented headset's data collected from actual space and the objects cataloged from the user's own personal inventory and third party vendor sites.

The method is also for architectural firms and engineers to also prepopulate vacant buildings in real time and collaborate with others on architectural projects.

The expected users for such an invention are real estate professionals, real estate customers, interior designers, retail outlets and other home improvement, furniture, and appliance/electronics retail stores, and the casual home owner/renter.

The benefits to the customer is actually visualizing in real time how a specific product looks like in an augmented reality setting where virtual objects are superimposed on their real surrounding environment, which in most cases will be vacant rooms/buildings. Government run agencies can utilize the system to place items prior to expansion or renovation. An example could be a hospital under expansion that needs to plan equipment placement, such as hospital beds, cabinets, and medical equipment, in real time. A planner could walk into the vacant space and select items from a medical supply company inventory website and then place the objects in real-time using the augmented reality headset. The user can then create a list of items needed for each room and order directly from the vendor all through the headset software.

Having described my invention, I claim:

1. The ability to place objects into a real 3D space for the user to visualize placement in a real world setting utilizing an augmented reality headset.

2. Creating a 3D model based upon photographs taken by a cellphone.

3. Accessing and downloading third party vendor 3D models of products for use within the augmented reality headset.

4. Creating an inventory list of user generated and vendor provided 3D models accessible through cellphone or augmented reality headset.

5. Utilizing an augmented reality headset to place holograms of user generated 3D models and third party vendor provided 3D models in real world environments for interior design placement.

6. A process for adding third party vendor products to a shopping cart.

7. A process for purchasing third party vendor products that were selected by the user through the use of the augmented reality headset.

8. Creating a digital blueprint of a space based on measurement data collected by the augmented reality headset and the holograms placed within by the user.
